(19) United States
(12) Patent Application Publication
(10) Pub. No.: US 2022/0194791 A1
(43) Pub. Date: Jun. 23, 2022

(54) METHOD FOR PRODUCING AQUEOUS SOLUTION OF PURIFIED ORTHOPERIODIC ACID, METHOD FOR PRODUCING SEMICONDUCTOR DEVICE, AND AQUEOUS SOLUTION OF ORTHOPERIODIC ACID

(71) Applicant: TOKYO OHKA KOGYO CO., LTD., Kawasaki-shi (JP)

(72) Inventors: Hiroshi ITO, Kawasaki-shi (JP); Yukihisa WADA, Kawasaki-shi (JP)

(21) Appl. No.: 17/457,333

(22) Filed: Dec. 2, 2021

(30) Foreign Application Priority Data
Dec. 22, 2020 (JP) 2020-212724
Oct. 12, 2021 (JP) 2021-167645

(51) Int. Cl. C01B 11/22; B01J 39/07; B01J 47/02; H01L 21/3213; B01D 15/36; B01D 15/38

(52) U.S. Cl. CPC C01B 11/22; B01J 39/07; B01J 47/02; C01P 2006/80; B01D 15/362; B01D 15/3828; H01L 21/32134

(57) ABSTRACT

A method for producing an aqueous solution of purified orthoperiodic acid with a reduced Cr content; a method for producing a semiconductor device that includes etching a Ru layer on a semiconductor substrate with an etchant obtained by the method; and an aqueous solution of orthoperiodic acid with a reduced Cr content. The method includes bringing an aqueous solution of crude orthoperiodic acid into contact with a metal removing agent including a chelating resin, the aqueous solution of crude orthoperiodic acid containing orthoperiodic acid and water and having an orthoperiodic acid content of 15% by mass or less and a Cr content of 1 ppb by mass or more based on the total mass of the aqueous solution of crude orthoperiodic acid.

### RELATED APPLICATIONS

This application claims priority to Japanese Patent Application No. 2020-212724, filed Dec. 22, 2020; and Japanese Patent Application No. 2021-167645, filed Oct. 12, 2021, the entire contents of which are incorporated herein by reference.

### BACKGROUND OF THE INVENTION

### Field of the Invention

The present invention relates to a method for producing an aqueous solution of purified orthoperiodic acid, a method for producing a semiconductor device, and an aqueous solution of orthoperiodic acid.

### Related Art

For next generation semiconductor devices, studies have been conducted on changing wiring metal from copper (Cu) in current use to ruthenium (Ru) in order to improve performance. An orthoperiodic acid-containing aqueous solution is known as an etchant capable of etching Ru and available for the process of forming Ru wiring layers on a semiconductor substrate or removing Ru from the surface of a semiconductor substrate (see, for example, Patent Documents 1 and 2).
Patent Document 1: Japanese Unexamined Patent Application, Publication No. 2016-92101
Patent Document 2: Pamphlet of PCT International Publication No. WO2019/150990

### SUMMARY OF THE INVENTION

Unfortunately, a minute amount of metal impurities in etchants causes a problem in semiconductor device processes. A high level of removal of metal impurities is required also for the orthoperiodic acid-containing etchant disclosed in Patent Document 2, and at present, processes for purifying such an etchant are being developed aggressively.

As a result of investigation, the present inventors have come to learn that orthoperiodic acid products for use in etchants contain a relatively large amount of chromium (Cr) depending on the manufacturer and manufacturing process.

In this regard, the present inventors also have found that the prior art cannot efficiently remove the Cr by itself.

It is an object of the present invention to provide a method for producing an aqueous solution of purified orthoperiodic acid with a reduced Cr content; a method for producing a semiconductor device that includes etching a Ru layer on a semiconductor substrate with an etchant obtained by the method; and an aqueous solution of orthoperiodic acid with a reduced Cr content.

A first aspect of the present invention relates to a method for producing an aqueous solution of purified orthoperiodic acid, the method including a metal removal step including bringing an aqueous solution of crude orthoperiodic acid into contact with a metal removing agent including a chelating resin, the aqueous solution of crude orthoperiodic acid containing orthoperiodic acid and water and having an orthoperiodic acid content of 15% by mass or less and a Cr content of 1 ppb by mass or more based on the total mass of the aqueous solution of crude orthoperiodic acid.

A second aspect of the present invention relates to a method for producing a semiconductor device, the method including: etching a Ru layer on a semiconductor substrate with a Ru etchant produced by the method according to the first aspect of the present invention.

A third aspect of the present invention relates to an orthoperiodic acid aqueous solution including orthoperiodic acid and water and having an orthoperiodic acid content of 15% by mass or less and a Cr content of 1 ppt by mass or more and less than 1 ppb by mass based on the total mass of the aqueous solution.

The present invention makes it possible to provide a method for producing an aqueous solution of purified orthoperiodic acid with a reduced Cr content, to provide a method for producing a semiconductor device that includes etching a Ru layer on a semiconductor substrate with an etchant obtained by such a method, and to provide an aqueous solution of orthoperiodic acid with a reduced Cr content.

### DETAILED DESCRIPTION OF THE INVENTION

<Method for Producing Aqueous solution of Purified Orthoperiodic Acid>

The method for producing an aqueous solution of purified orthoperiodic acid includes a metal removal step including bringing an aqueous solution of crude orthoperiodic acid into contact with a metal removing agent including a chelating resin, in which the aqueous solution of crude orthoperiodic acid contains orthoperiodic acid (H₅IO₆) and water. The aqueous solution of crude orthoperiodic acid has an orthoperiodic acid content of 15% by mass or less based on the total mass of the aqueous solution of crude orthoperiodic acid. The aqueous solution of crude orthoperiodic acid also has a Cr content of 1 ppb by mass or more based on the total mass of the aqueous solution of crude orthoperiodic acid.

Hereinafter, the metal removal step in the method for producing an aqueous solution of purified orthoperiodic acid will be described.

### [Metal Removal Step]

### (Aqueous Solution of Crude Orthoperiodic Acid)

In the metal removal step, an aqueous solution of crude orthoperiodic acid is used as a target to be purified. The aqueous solution of crude orthoperiodic acid contains orthoperiodic acid and water. The aqueous solution of crude orthoperiodic acid has an orthoperiodic acid content of 15% by mass or less based on the total mass of the aqueous solution of crude orthoperiodic acid. For ease of good removal of Cr, the content of orthoperiodic acid is preferably 0.01% by mass or more and 10% by mass or less, and more preferably 0.1% by mass or more and 7% by mass or less.

In the metal removal step, at least Cr is removed among metal impurities in the aqueous solution of crude orthoperiodic acid. The content of Cr in the aqueous solution of crude orthoperiodic acid is 1 ppb by mass or more based on the total mass of the aqueous solution of crude orthoperiodic acid. For ease of obtaining an aqueous solution of purified orthoperiodic acid through sufficient removal of Cr in the metal removal step, the content of Cr in the aqueous solution of crude orthoperiodic acid is preferably 1 ppb by mass or more and 100 ppb by mass or less, and more preferably 1 ppb by mass or more and 60 ppb by mass or less.

In the metal removal step, tin (Sn) is also preferably removed from the aqueous solution of crude orthoperiodic acid. For ease of obtaining an aqueous solution of purified orthoperiodic acid through sufficient removal of Sn, the content of Sn in the aqueous solution of crude orthoperiodic acid is preferably 60 ppb by mass or less, and more preferably 1 ppb by mass or more and 30 ppb by mass or less.

In the metal removal step, metal impurities other than Cr and Sn (hereinafter also referred to as “other metal impurities”) are also preferably removed from the aqueous solution of crude orthoperiodic acid solution. Examples of other metal impurities, which are preferably removed in the metal removal step, include lithium (Li), sodium (Na), magnesium (Mg), aluminum (Al), potassium (K), calcium (Ca), titanium (Ti), vanadium (V), manganese (Mn), iron (Fe), cobalt (Co), nickel (Ni), copper (Cu), zinc (Zn), strontium (Sr), molybdenum (Mo), silver (Ag), cadmium (Cd), antimony (Sb), barium (Ba), tungsten (W), and lead (Pb).

As long as the advantageous effects of the present invention are not impaired, the aqueous solution of crude orthoperiodic acid may contain an additional component other than orthoperiodic acid and water (hereinafter also referred to as the “additional component”). The additional component may be, for example, a pH adjusting agent.

### (Metal Removing Agent Including Chelating Resin)

In the metal removal step, the aqueous solution of crude orthoperiodic acid is treated with a metal removing agent including a chelating resin.

The chelating resin used in the metal removal step refers to a resin having a functional group that has been introduced into the matrix of the resin and is capable of forming chelates with metal ions. Examples of the resin matrix include, but are not limited to, styrene-divinylbenzene copolymers, epoxy resins, phenolic resins, resorcinol resins, and vinyl chloride resins. Examples of the functional group introduced include, but are not limited to, an aminomethylphosphonic acid group, an aminophosphoric acid group, an iminodiacetic acid group, a polyamine group, and a glucamine group. In the description, regarding the name of the chelating resin, for example, a chelating resin having an aminomethylphosphonic acid group as the introduced functional group is also referred to as an “aminomethylphosphonic acid type chelating resin”.

In the metal removal step, the aqueous solution of crude orthoperiodic acid is brought into contact with the metal removing agent including the chelating resin. The aqueous solution of crude orthoperiodic acid may be brought into contact with the metal removing agent by any appropriate method, which may include, for example, allowing the aqueous solution of crude orthoperiodic acid to pass through a vessel, such as a column, filled with the metal removing agent or immersing the metal removing agent into the aqueous solution of crude orthoperiodic acid.

The aqueous solution of crude orthoperiodic acid may be brought into contact with the metal removing agent under any appropriate conditions. For example, the aqueous solution of crude orthoperiodic acid is preferably brought into contact with the metal removing agent at a temperature of 10° C. or more and 40° C. or less. The aqueous solution of crude orthoperiodic acid may be brought into contact with the metal removing agent for any appropriate period of time. For example, the aqueous solution of crude orthoperiodic acid is preferably brought into contact with the metal removing agent for a time period of 1 minute or more and 4 hours or less.

A specific method for allowing the aqueous solution of crude orthoperiodic acid to pass through a vessel filled with the metal removing agent may include, for example, feeding the aqueous solution of crude orthoperiodic acid to the vessel filled with a chelating resin to bring the aqueous solution into contact with the chelating resin in the vessel; and collecting an effluent resulting from the contact of the aqueous solution with the chelating resin and flowing out of the vessel. When at a desired purity level, the effluent corresponds to the aqueous solution of purified orthoperiodic acid. When not at a desired purity level, the effluent may be subjected as the aqueous solution of crude orthoperiodic acid to further purification. The purity level, which is used to distinguish between the aqueous solution of crude orthoperiodic acid and the aqueous solution of purified orthoperiodic acid, may be appropriately determined depending on the requirements of the etching process to be performed using the purified orthoperiodic acid as an etchant.

The vessel may be any type. The vessel may be, for example, a column for use in column chromatography. Any feeding method may be used to feed the aqueous solution of crude orthoperiodic acid. The feeding method may be, for example, a method using the gravity acting on the aqueous solution of crude orthoperiodic acid placed at a position higher than that of the inlet of the vessel, or a method using a difference between the pressure in the vessel and the pressure in the reservoir containing the aqueous solution of crude orthoperiodic acid. The pressure difference may be generated by a method of reducing the pressure in the vessel, a method of increasing the pressure in the reservoir containing the aqueous solution of crude orthoperiodic acid, or a method of pressurizing the aqueous solution of crude orthoperiodic acid using a pump or the like. The process of allowing the aqueous solution of crude orthoperiodic acid to flow through the vessel filled with the chelating resin may be performed at any space velocity (SV). For ease of successful removal of metal impurities including Cr, the space velocity (SV) is preferably 25 (L/h) or less, and more preferably 10 (L/h) or less.

A method of immersing the metal removing agent in the aqueous solution of crude orthoperiodic acid may include, for example, placing the metal removing agent in a vessel; adding the aqueous solution of crude orthoperiodic acid to the vessel; stirring the aqueous solution and/or allowing the aqueous solution to stand; and collecting an aqueous solution of orthoperiodic acid resulting from the contact with the metal removing agent. The aqueous solution of orthoperiodic acid resulting from the contact with the metal removing agent may be collected by decantation, solid-liquid separation using a known filtration apparatus, or any other appropriate method.

In the metal removal step, the chelating resin may be used in combination with an ion-exchange resin. Any method may be used when the chelating resin is used in combination with an ion-exchange resin. For example, the aqueous solution of crude orthoperiodic acid may be brought into contact with a cation-exchange resin before or after being brought into contact with the chelating resin. In this process, the chelating resin functions as a first metal removing agent while the cation-exchange resin functions as a second metal removing agent, and the aqueous solution of crude orthoperiodic acid may be brought into contact with the first metal removing agent and then with the second metal removing agent or into contact with the second metal removing agent and then with the first metal removing agent. The use of the chelating resin in combination with the cation-exchange resin makes it possible to remove other metal impurities, which cannot be sufficiently removed using only the chelating resin.

In an alternative method, the chelating resin and the ion-exchange resin may be used together at the same time. The method in which they are used together at the same time may include, for example, preparing a mixture of the chelating resin and the cation-exchange resin; and bringing the aqueous solution of crude orthoperiodic acid into contact with the mixture as the metal removing agent.

The cation-exchange resin may be a strongly acidic, cation-exchange resin having a strong acid group, such as a sulfonic acid group, or a weakly acidic, cation-exchange resin having a weak acid group, such as a carboxyl group, a phosphonic acid group, or a phosphinic acid group. Among them, a cation-exchange resin having a sulfonic acid group is preferred.

### (Aqueous Solution of Purified Orthoperiodic Acid)

The metal removal step yields an aqueous solution of purified orthoperiodic acid, which results from the removal of Cr from the aqueous solution of crude orthoperiodic acid. The content of Cr in the aqueous solution of purified orthoperiodic acid is preferably 1 ppb by mass or less, more preferably 1 ppt by mass or more and 0.7 ppb by mass or less, and still more preferably 1 ppt by mass or more and 0.5 ppb by mass or less, based on the total mass of the aqueous solution of purified orthoperiodic acid.

The content of Sn in the aqueous solution of purified orthoperiodic acid is preferably 1 ppb by mass or less, more preferably 1 ppt by mass or more and 0.7 ppb by mass or less, and still more preferably 1 ppt by mass or more and 0.5 ppb by mass or less, based on the total mass of the aqueous solution of purified orthoperiodic acid.

The aqueous solution of purified orthoperiodic acid is a suitable etchant for Ru. The aqueous solution of purified orthoperiodic acid, which has a reduced Cr content, is less likely to cause a Cr-induced defect, which would otherwise be caused by a small amount of Cr, in the process of manufacturing semiconductor devices having Ru wiring.

### <Method for Producing Semiconductor Device>

A method for producing a semiconductor device includes etching a Ru layer on a semiconductor substrate with a Ru etchant produced by the method described above. The method of forming the Ru layer on the semiconductor substrate may be any known method, such as sputtering, chemical vapor deposition (CVD), molecular beam epitaxy (MBE), or atomic layer deposition (ALD).

The etching may be performed using any known etching method, such as a spray method, a dipping method, or a liquid puddle forming method.

The spray method may include, for example, rotating or moving, in a predetermined direction, the semiconductor substrate provided with the Ru layer; and spraying the etchant into the space above the substrate to bring the etchant into contact with the semiconductor substrate. If necessary, a spin coater may be used to rotate the substrate while the etchant is sprayed.

The dipping method may include dipping the semiconductor substrate in the etchant to bring the semiconductor substrate into contact with the etchant.

The liquid puddle forming method may include forming a puddle of the etchant on the semiconductor substrate to bring the semiconductor substrate into contact with the etchant.

One of these etching methods may be appropriately selected depending on the structure, material, or other features of the semiconductor substrate.

### <Orthoperiodic Acid Aqueous Solution>

The orthoperiodic acid aqueous solution includes orthoperiodic acid and water. The content of orthoperiodic acid in the orthoperiodic acid aqueous solution is 15% by mass or less based on the total mass of the orthoperiodic acid aqueous solution. The content of Cr in the orthoperiodic acid aqueous solution is 1 ppt by mass or more and less than 1 ppb by mass based on the total mass of the orthoperiodic acid aqueous solution. The method for producing the orthoperiodic acid aqueous solution with such features is typically, but not limited to, the production method described above.

The content of orthoperiodic acid in the orthoperiodic acid aqueous solution is preferably 0.01% by mass or more and 10% by mass or less, and more preferably 0.1% by mass or more and 7% by mass or less. The content of Cr in the orthoperiodic acid aqueous solution is more preferably 1 ppt by mass or more and 0.7 ppb by mass or less, and still more preferably 1 ppt by mass or more and 0.5 ppb by mass or less.

The content of Sn in the orthoperiodic acid aqueous solution is preferably 60 ppb by mass or less, and more preferably 1 ppb by mass or more and 30 ppb by mass or less, based on the total mass of the orthoperiodic acid aqueous solution.

The orthoperiodic acid aqueous solution is a suitable etchant for Ru. The orthoperiodic acid aqueous solution, which has a reduced Cr content, is less likely to cause a Cr-induced defect, which would otherwise be caused by a small amount of Cr, in the process of manufacturing semiconductor devices having Ru wiring.

### EXAMPLES

Hereinafter, the present invention will be more specifically described with reference to examples and comparative examples. It will be understood that the examples shown below are not intended to limit the present invention.

### Examples 1 to 5 and Comparative Example 1

### (Preparation of Aqueous Solution of Crude Orthoperiodic Acid)

Aqueous solutions A1, A2, A3, and A4 of crude orthoperiodic acid were prepared by dissolving different amounts of an orthoperiodic acid product in water.

A1: 1.5 mass % by mass orthoperiodic acid aqueous solution
A2: 5% by mass orthoperiodic acid aqueous solution
A3: 10% by mass orthoperiodic acid aqueous solution
A4: 20% by mass orthoperiodic acid aqueous solution

### (Metal Removal Step)

A column with an inner volume of 60 mL was filled with a chelating resin (MC960 manufactured by Sumika Chemtex Company, Limited, aminomethylphosphonic acid type). Each of the aqueous solutions A1 to A4 of crude orthoperiodic acid was allowed to pass through the column at the space velocity (SV) shown in Table 1 while an aqueous solution of purified orthoperiodic acid following out of the column was collected. When the solution was allowed to pass, the chelating resin and the aqueous solution of crude orthoperiodic acid were both at a temperature of 25° C.

### (Measurement of Cr Content)

The content of Cr in the aqueous solution of crude orthoperiodic acid and the content of Cr in the aqueous solution of purified orthoperiodic acid resulting from the metal removal step were measured using Agilent ICP-MS (manufactured by Agilent Technologies). The results are shown in Table 1.

TABLE 1

| | Aqueous solution of | | | Metal | Aqueous solution of | |
|---|---|---|---|---|---|---|
| | crude orthoperiodic acid | | | removel | purified orthoperiodic acid | |
| | | Orthoperiodic | Cr | step | Cr | Cr |
| | | acid content | content | SV | content | removal |
| | Type | (% by mass) | (ppb by mass) | (1/h) | (ppb by mass) | ratio (%) |
| Example 1 | A1 | 1.5 | 13.2 | 5 | 0.03 | 99.8 |
| Example 2 | A2 | 5 | 44 | 5 | 0.6 | 98.6 |
| Example 3 | A2 | 5 | 44 | 10 | 0.7 | 98.4 |
| Example 4 | A2 | 5 | 44 | 50 | 5 | 88.6 |
| Example 5 | A3 | 10 | 88 | 10 | 6.3 | 92.8 |
| Comparative | A4 | 20 | 176 | 10 | 35.5 | 79.8 |
| Example 1 | | | | | | |

The results of Examples 3 and 5 and Comparative Example 1 indicate that the Cr removal ratio increases with decreasing content of orthoperiodic acid in the aqueous solution of crude orthoperiodic acid. The results of Examples 2 to 4 also indicate that the Cr removal ratio increase with decreasing SV of the solution being allowed to pass.

### Example 6

The contents of Li, Na, Mg, Al, K, Ca, Ti, V, Cr, Mn, Fe, Co, Ni, Cu, Zn, Sr, Mo, Ag, Cd, Sn, Sb, Ba, W, and Pb in the aqueous solution of crude orthoperiodic acid and in the aqueous solution of purified orthoperiodic acid resulting from the metal removal step in Example 2 were measured using Agilent ICP-MS (manufactured by Agilent Technologies). The results are shown in Table 2.

TABLE 2

| | Aqueous solution of | Aqueous solution of |
|---|---|---|
| | crude orthoperiodic acid | purified orthoperiodic acid |
| Metal | Metal content (ppb by mass) | Metal content (ppb by mass) |
| Li | <0.5 | <0.5 |
| Na | 62.0 | 61.9 |
| Mg | 3.2 | 2.0 |
| Al | 4.5 | <0.5 |
| K | 1.6 | 0.5 |
| Ca | 29.7 | 2.0 |
| Ti | 0.7 | <0.5 |
| V | <0.5 | <0.5 |
| Cr | 46.6 | 0.5 |
| Mn | 2.2 | <0.5 |
| Fe | 5.4 | <0.5 |
| Co | <0.5 | <0.5 |
| Ni | <0.5 | 2.0 |
| Cu | 0.6 | <0.5 |
| Zn | 1.6 | 2.3 |
| Sr | <0.5 | <0.5 |
| Mo | 5.1 | 0.6 |
| Ag | <0.5 | <0.5 |
| Cd | 1.0 | <0.5 |
| Sn | 31.3 | <0.5 |
| Sb | <0.5 | <0.5 |
| Ba | 3.3 | <0.5 |
| W | <0.5 | <0.5 |
| Pb | 1.5 | <0.5 |

The results in Table 2 indicate that a high Sn removal ratio is achieved even when the aqueous solution of crude orthoperiodic acid has a relatively high Sn content of 31.3 ppb by mass.

### Example 7

Two columns were provided one of which was filled with a chelating resin (MC960 manufactured by Sumika Chemtex Company, Limited, aminomethylphosphonic acid type) and the other of which was filled with a cation-exchange resin (DS-1 manufactured by Organo Corporation, sulfonic acid type). The two columns each have an inner volume of 60 mL. The two columns were then connected such that the chelating resin-filled column and the cation-exchange resin-filled column were respectively located upstream and downstream for the flow of the aqueous solution of crude orthoperiodic acid. The aqueous solution A1 of crude orthoperiodic acid, which was used in Examples 1 to 5 and Comparative Example 1, was allowed to pass through the connected columns at a space velocity of 5 (L/h). An aqueous solution of purified orthoperiodic acid was collected, which flowed out of the cation-exchange resin-filled column. When the solution was allowed to pass, the chelating resin, the cation-exchange resin, and the aqueous solution A1 of crude orthoperiodic acid were all at a temperature of 25° C.

The contents of metal impurities in the aqueous solution of crude orthoperiodic acid and in the aqueous solution of purified orthoperiodic acid were measured as in Example 6. The results are shown in Table 3.

TABLE 3

| | Aqueous solution of | Aqueous solution of |
|---|---|---|
| | crude orthoperiodic acid | purified orthoperiodic acid |
| Metal | Metal content (ppb by mass) | Metal content (ppb by mass) |
| Li | <0.5 | <0.02 |
| Na | 17.30 | 0.35 |
| Mg | <0.5 | <0.02 |
| Al | <0.5 | 0.06 |
| K | <0.5 | 0.07 |
| Ca | 2.07 | 0.20 |
| Ti | 0.70 | <0.02 |
| V | <0.5 | <0.02 |
| Cr | 16.99 | 0.11 |
| Mn | 0.85 | 0.15 |
| Fe | 1.59 | 0.04 |
| Co | <0.5 | <0.02 |
| Ni | <0.5 | <0.02 |
| Cu | <0.5 | <0.02 |
| Zn | <0.5 | 0.08 |
| Sr | <0.5 | <0.02 |
| Mo | 1.66 | <0.02 |
| Ag | <0.5 | <0.02 |
| Cd | <0.5 | <0.02 |
| Sn | 8.31 | 0.07 |
| Sb | <0.5 | <0.02 |
| Ba | 1.04 | <0.02 |
| W | <0.5 | <0.02 |
| Pb | <0.5 | <0.02 |

The results in Table 3 indicate that the content of each metal impurity was successfully reduced to at most 0.5 ppb by mass when the crude orthoperiodic acid aqueous solution with an orthoperiodic acid content of 1.5% by mass was used.

### Example 8

Two columns (each 60 mL in inner volume) were provided one of which was filled with a chelating resin (MC960 manufactured by Sumika Chemtex Company, Limited, aminomethylphosphonic acid type) and the other of which was filled with a cation-exchange resin (DS-1 manufactured by Organo Corporation, sulfonic acid type). A crude aqueous solution of 0.75% by mass orthoperiodic acid was allowed to pass through each of the columns at a space velocity (SV) of 5 (L/h) while an aqueous solution of purified orthoperiodic acid flowing out of each column was collected.

The Na, Cr, and Sn contents of the crude aqueous solution of 0.75% orthoperiodic acid were measured by the same method as that in Example 6. The Cr and Sn contents of the aqueous solution of purified orthoperiodic acid, which was collected from the chelating resin-filled column, were measured by the same method as that in Example 6 at the time points when the collected volumes shown in Table 4 were reached. The Na content of the aqueous solution of purified orthoperiodic acid, which was collected from the cation-exchange resin-filled column, was measured by the same method as that in Example 6 at the time points when the collected volumes shown in Table 4 were reached. When the solution was allowed to pass, the chelating resin, the cation-exchange resin, and the aqueous solution of crude orthoperiodic acid were all at a temperature of 25° C. The results are shown in Table 4.

TABLE 4

| | | Na content | Cr content | Sn content |
|---|---|---|---|---|
| | | (ppb by mass) | (ppb by mass) | (ppb by mass) |
| | | Unpurified product | | |
| Collected volume | | 9.06 | 8.21 | 2.82 |
| 0.5 | L | 0.37 | 0.02 | 0.03 |
| 1 | L | 0.38 | 0.07 | <0.02 |
| 2 | L | 0.34 | 0.05 | <0.02 |
| 3 | L | 0.35 | 0.11 | <0.02 |
| 4 | L | 0.35 | 0.08 | <0.02 |
| 5 | L | 0.36 | 0.10 | <0.02 |
| 6 | L | 0.43 | 0.03 | <0.02 |
| 7 | L | 0.95 | <0.5 | <0.5 |
| 8 | L | 2.12 | <0.5 | <0.5 |
| 9 | L | 4.65 | <0.5 | <0.5 |
| 10 | L | 7.00 | <0.5 | <0.5 |
| 11 | L | 8.27 | <0.5 | <0.5 |
| 12 | L | 8.89 | <0.5 | <0.5 |
| 13 | L | 8.94 | <0.5 | <0.5 |

The results in Table 4 indicate that the chelating resin with high ability to remove Cr and Sn has a lifetime longer than that of the cation-exchange resin with high ability to remove Na.

### Example 9

Wafers were washed with the aqueous solution of purified orthoperiodic acid, and then the number of particles on the wafers was evaluated.

Specifically, 40 L of the aqueous solution A1 of crude orthoperiodic acid used in Example 7 was provided, and 40 L of the aqueous solution of purified orthoperiodic acid obtained in Example 7 was provided. Each of the aqueous solutions was subjected to filtration for 2 hours using a polytetrafluoroethylene (PTFE) filter (manufactured by Entegris, 15 nm in pore size) so that particles were removed from each aqueous solution. Each of the filtered aqueous solutions was used as a single-use clearing liquid. In a piece-by-piece cleaning apparatus for 300 mm wafer, a piece of bare-Si wafer was washed with the cleaning liquid at a flow rate of 1.5 L/min, 23° C., and 500 rpm for 3 minutes, then washed with water, and then dried. The experiment shown above was conducted three times using each of the aqueous solution of purified orthoperiodic acid and the aqueous solution of crude orthoperiodic acid, in which three bare-Si wafers in total were treated with each of the aqueous solutions. After the drying, the number of particles on each bare-Si wafer was measured using SP5 manufactured by KLA Corporation. Table 5 shows the numbers of particles in the first, second, and third experiments and their average. In the measurement, particles with diameters of at least 26 nm were counted.

TABLE 5

| | Aqueous solution of | Aqueous solution of |
|---|---|---|
| | crude orthoperiodic acid | purified orthoperiodic acid |
| First | 13 particles | 7 particles |
| Second | 18 particles | 9 particles |
| Third | 17 particles | 11 particles |
| Average | 16 particles | 9 particles |

The results in Table 5 indicate that the average number of particles on the wafer treated with the aqueous solution of purified orthoperiodic acid is 9, which is lower than 16, the average number of particles on the wafer treated with the aqueous solution of crude orthoperiodic acid. This would be because metal impurities such as Cr and Sn were successfully removed using the aqueous solution of purified orthoperiodic acid.

What is claimed is:

1. A method for producing an aqueous solution of purified orthoperiodic acid,
the method comprising bringing an aqueous solution of crude orthoperiodic acid into contact with a metal removing agent comprising a chelating resin,
wherein the aqueous solution of crude orthoperiodic acid contains orthoperiodic acid and water and has an orthoperiodic acid content of 15% by mass or less and a Cr content of 1 ppb by mass or more based on a total mass of the aqueous solution of crude orthoperiodic acid.

2. The method according to claim 1, wherein the aqueous solution of crude orthoperiodic acid has a Cr content of 100 ppb by mass or less.

3. The method according to claim 1, wherein the aqueous solution of crude orthoperiodic acid further contains 1 ppb by mass or more of Sn.

4. The method according to claim 1, wherein the aqueous solution of crude orthoperiodic acid has a Sn content of 60 ppb by mass or less.

5. The method according to claim 1, wherein the metal removal is carried out at a space velocity (SV) of 25 L/hour.

6. The method according to claim 1, wherein the metal removal step comprises bringing the aqueous solution of crude orthoperiodic acid into contact with a metal removing agent comprising a cation-exchange resin before or after the aqueous solution of crude orthoperiodic acid is brought into contact with the metal removing agent comprising the chelating resin.

7. The method according to claim 1, wherein the metal removing agent is a mixture of the chelating resin and a cation-exchange resin.

8. The method according to claim 1, wherein the chelating resin is an aminomethylphosphonic acid-type resin.

9. The method according to claim 1, wherein the aqueous solution of purified orthoperiodic acid is an etchant for Ru.

10. The method according to claim 9, wherein the etchant for Ru has a Cr content of 1 ppb by mass or less.

11. A method for producing a semiconductor device, the method comprising etching a Ru layer on a semiconductor substrate with a Ru etchant produced by the method according to claim 9.

12. An orthoperiodic acid aqueous solution comprising orthoperiodic acid and water and having an orthoperiodic acid content of 15% by mass or less and a Cr content of 1 ppb by mass or more and less than 1 ppb by mass based on a total mass of the aqueous solution.
